(19) United States
(12) Patent Application Publication
(10) Pub. No.: US 2025/0096183 A1
(43) Pub. Date: Mar. 20, 2025

(54) METHOD OF MANUFACTURING SEMICONDUCTOR DEVICE, METHOD OF MANUFACTURING SEMICONDUCTOR MODULE, AND SEMICONDUCTOR DEVICE

(71) Applicant: RENESAS ELECTRONICS AMERICA INC., MILPITAS, CA (US)

(72) Inventor: Martin Ashley VAGUES, Livemore, CA (US)

(73) Assignee: RENESAS ELECTRONICS AMERICA INC., MILPITAS, CA (US)

(21) Appl. No.: 18/470,781

(22) Filed: Sep. 20, 2023

(51) Int. Cl. H01L 23/00; H01L 21/56; H01L 25/00; H01L 25/18

(52) U.S. Cl. CPC H01L 24/27; H01L 21/56; H01L 24/06; H01L 24/29; H01L 24/32; H01L 24/48; H01L 24/49; H01L 24/73; H01L 24/83; H01L 24/92; H01L 25/18; H01L 25/50; H01L 2224/06181; H01L 2224/27312; H01L 2224/2929; H01L 2224/29339; H01L 2224/29386; H01L 2224/32227; H01L 2224/32245; H01L 2224/48091; H01L 2224/48106; H01L 2224/48108; H01L 2224/48137; H01L 2224/48229; H01L 2224/49175; H01L 2224/73265; H01L 2224/83022; H01L 2224/83192; H01L 2224/83986; H01L 2224/92247; H01L 2924/05032; H01L 2924/0665; H01L 2924/10253; H01L 2924/10272; H01L 2924/10329; H01L 2924/1033

(57) ABSTRACT

A method includes preparing a substrate; cleaning a chip mounting surface of the substrate; supplying a homogenized die-bonding paste onto the chip mounting surface, and attaching a semiconductor chip on the chip mounting surface via the homogenized die-bonding paste, the semiconductor chip having a front surface, a back surface opposite the front surface, and a first electrode formed on the front surface; curing the homogenized die-bonding paste; electrically connecting the first electrode with a first terminal of the substrate via a first wire; and sealing the semiconductor chip and the first wire with a sealing resin, wherein the homogenized die-bonding paste used in supplying is initially provided as an unstirred die-bonding paste including a plurality of Ag fillers, and wherein, in supplying, the homogenized die-bonding paste is supplied onto the chip mounting surface after the unstirred die-bonding paste along with Ag fillers is stirred for a first predetermined time period.

### BACKGROUND

Unless otherwise indicated herein, the materials described in this section are not prior art to the claims in this application and are not admitted to be prior art by inclusion in this section. The present disclosure relates in general to systems and methods of reliably manufacturing a semiconductor device and a semiconductor module, more particularly, to manufacturing a semiconductor device including one high-power semiconductor chip and a semiconductor module that may include two or more high-power semiconductor chips that are likely to experience high temperatures.

Thermal challenges are expected for electronic systems using high-powered electronic devices, and heat dissipation is a ubiquitous concern for many designers. Various techniques may be employed such as encapsulation to surround and conduct heat directly away from hot components, and the like. However, thermal excursions (e.g., changes or swings in temperature) may create mechanical stresses that can cause breakage over time. Hence, the thermal, mechanical, and electrical characteristics of various encapsulating materials must be carefully considered. Some designers may elect to limit performance to reduce risk of breakage, for example. Other designers may select exotic materials that are more tolerant to higher thermal excursions, but at significantly increased cost. Neither of these alternatives may be appealing to those who are pursuing greater performance, higher reliability, and a lower cost.

Various solutions have been attempted including mounting a semiconductor chip on a substrate via a porous, sintered silver (Ag) layer covered by a resin portion as a die-bonding layer, such as an example disclosed in U.S. Published Patent Application US 20140264383, titled Semiconductor device and manufacturing method of the same, and assigned to Applicant.

Another solution includes applying a die-bonding material using a stamping nozzle with a dug portion (e.g., a space portion) for holding a quantity of the die-bonding material, such as an example disclosed in U.S. Published Patent Application US 20130009300, titled Semiconductor device and manufacturing method of the same, and assigned to Applicant.

Yet another solution includes a compression molding method suitable for use with a molding of a large substrate, such as an example disclosed in U.S. Published Patent Application US 20220068668, titled Method of manufacturing semiconductor device, and assigned to Applicant. What is needed is a solution that addresses these issues, and others.

### SUMMARY

According to an example, a method of manufacturing a semiconductor device is generally described. The method of manufacturing a semiconductor device may include: (a) preparing a substrate; (b) after (a), cleaning a chip mounting surface of the substrate; (c) after (b), supplying a homogenized die-bonding paste onto the chip mounting surface of the substrate, and attaching a semiconductor chip on the chip mounting surface of the substrate via the homogenized die-bonding paste, the semiconductor chip having a front surface, a back surface opposite the front surface, and a first electrode formed on the front surface; (d) after (c), curing the homogenized die-bonding paste; (e) after (d), electrically connecting the first electrode of the semiconductor chip with a first terminal of the substrate via a first wire; and (f) after (e), sealing the semiconductor chip and the first wire with a sealing resin, wherein the homogenized die-bonding paste used in (c) may be initially provided as an unstirred die-bonding paste including a plurality of Ag fillers, and wherein, in (c), the homogenized die-bonding paste may be supplied onto the chip mounting surface of the substrate after the unstirred die-bonding paste along with the plurality of Ag fillers may be stirred for a first predetermined time period.

According to this example, the method wherein, in (b), the chip mounting surface of the substrate may be cleaned by a plasma cleaning method using an Ar (Argon) gas. The method wherein the substrate may have: the first terminal; and a second terminal disposed on the chip mounting surface, wherein the semiconductor chip further may have: the front surface; the back surface opposite the front surface; the first electrode formed on the front surface; and a second electrode formed on the back surface, wherein, in (b), a surface of the first terminal and the chip mounting surface of the second terminal may be cleaned, wherein, in (c), the die-bonding paste may be supplied onto the chip mounting surface of the second terminal, and wherein, in (e), the second electrode of the semiconductor chip may be electrically connected with the second terminal of the substrate via the homogenized die-bonding paste. The method wherein, in (c), the semiconductor chip may be supplied onto the chip mounting surface of the substrate beginning within a second predetermined time period after the die-bonding paste may be supplied onto the chip mounting surface of the substrate.

According to this example, the method wherein the second predetermined time period may be less than sixty minutes. The method wherein, in (c), the homogenized die-bonding paste may be stirred with a vibration for the first predetermined time period before the homogenized die-bonding paste may be supplied onto the chip mounting surface of the substrate. The method wherein, in (c), the homogenized die-bonding paste may be stirred with a vibration at 40000 vibrations per minute for the first predetermined time period before the homogenized die-bonding paste may be dispensed onto the chip mounting surface of the substrate, and wherein the first predetermined time period may be at least 90 seconds and not more than 150 seconds. The method wherein the unstirred die-bonding paste used in (c) may be a silver-sintered epoxy paste including the plurality of Ag fillers. The method wherein the unstirred die-bonding paste used in (c) may be the silver-sintered epoxy paste including the plurality of Ag fillers and a plurality of AlN (Aluminum Nitride) fillers.

According to this example, the method wherein, in (c), the homogenized die-bonding paste may be supplied onto the chip mounting surface of the substrate by using a dispenser including: a nozzle; a syringe arranged above the nozzle and connected to the nozzle; and a piston arranged in the syringe, and wherein, in (c), the homogenized die-bonding paste may be stirred in the syringe, and may be dispensed onto the chip mounting surface of the substrate by pushing the homogenized die-bonding paste out with the piston. The method wherein the substrate may be a wiring substrate including a glass fiber and an epoxy resin, and wherein, in (f), the semiconductor chip and the wire are sealed with the sealing resin by using a compression molding method. The method may further include: (g) after (f), heating a molded package including the semiconductor chip, which may be obtained by performing (f), in a state that the molded package may be clamped with a first metal plate and a second metal plate.

According to another example, a method of manufacturing a semiconductor module is generally described. The method may include: (a) preparing a substrate having a chip mounting surface with a first bonding region and a second bonding region; (b) after (a), cleaning each of the first bonding region and the second bonding region; (c) after (b), supplying a homogenized die-bonding paste onto each of the first bonding region and the second bonding region; (d) after (c), attaching a first semiconductor chip on the first bonding region via the homogenized die-bonding paste supplied onto the first bonding region, the first semiconductor chip having a first front surface, a first back surface opposite the first front surface, and a first electrode formed on the first front surface; (e) after (d), attaching a second semiconductor chip on the second bonding region via the homogenized die-bonding paste supplied onto the second bonding region, the second semiconductor chip having a second front surface, a second back surface opposite the second front surface, and a second electrode formed on the second front surface; (f) after (e), curing the homogenized die-bonding paste supplied to each of the first bonding region and the second bonding region; (g) after (f), electrically connecting the first electrode of the first semiconductor chip with a first terminal of the substrate via a first wire, and electrically connecting the second electrode of the second semiconductor chip with a second terminal of the substrate via a second wire; and (h) after (g), sealing the first semiconductor chip, the second semiconductor chip, the first wire and the second wire with a sealing resin by compression molding, wherein the die-bonding paste used in (c) may be initially provided as an unstirred die-bonding paste including a plurality of Ag fillers, and wherein, in (c), the homogenized die-bonding paste may be supplied onto each of the first bonding region and the second bonding region after the unstirred die-bonding paste along with the plurality of Ag fillers may be stirred for a first predetermined time period.

According to this example, the method may further include: (i) after (h), heating a molded package including the first semiconductor chip and the second semiconductor chip, which may be obtained by performing (h), in a state that the molded package may be clamped between a first metal plate and a second metal plate. The method wherein, in (b), each of the first bonding region and the second bonding region may be cleaned by a plasma cleaning method using an Ar (Argon) gas. The method wherein the first semiconductor chip may be comprised of one of GaN and GaAs, wherein the second semiconductor chip may be comprised of one of Si and SiC, and wherein a flatness of the first back surface of the first semiconductor chip may be lower than a flatness of the second back surface of the second semiconductor chip.

According to yet another example, a semiconductor device is generally described. The semiconductor device may include a substrate; a semiconductor chip mounted on a chip mounting surface of the substrate via a homogenized die-bonding paste that may be cured; a wire electrically connected a first electrode of the semiconductor chip with a terminal; and a sealing body sealing the semiconductor chip and the wire, wherein the homogenized die-bonding paste may include a plurality of Ag fillers and a plurality of AlN fillers, wherein a density of the plurality of AlN fillers per unit volume may be less than a density of the plurality of Ag fillers per unit volume.

According to this example, the semiconductor device wherein a diameter of each of the plurality of AlN fillers may be smaller than a diameter of each of the plurality of Ag fillers. The semiconductor device wherein the semiconductor chip may further have: a front surface; a back surface opposite the front surface; the first electrode formed on the front surface; and a second electrode formed on the back surface, wherein the semiconductor chip may be mounted on the chip mounting surface of the substrate such that the back surface of the semiconductor chip faces the chip mounting surface of the substrate, and wherein the second electrode of the semiconductor chip may be electrically connected with the substrate via the homogenized die-bonding paste. The semiconductor device wherein the homogenized die-bonding paste may have been stirred at 40000 vibrations per minute for at least 90 seconds and not more than 150 seconds prior to mounting the semiconductor chip.

To be described more fully below, various examples herein are intended to address various problems such as improving the wettability of a die-bonding paste including a plurality of silver (Ag) fillers (e.g., silver-sintered epoxy paste) against a substrate as well as a semiconductor chip, which may include of one of Gallium Nitride (GaN), Gallium Arsenide (GaAs), Silicon Carbide (SiC), and/or Silicon Si) technologies, mounted onto the substrate. Various examples may also improve the electrical property of the die-bonding paste between the semiconductor chip and the substrate by distributing the plurality of Ag fillers homogenously. Various examples may also reduce warpage of a semiconductor substrate forming a semiconductor device or a semiconductor module.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates a block diagram view showing details of a manufacturing system that can produce a semiconductor device, in accordance with various examples of the present disclosure.

FIG. 2A-2E illustrate a side, partial cut-away view of a sequence of operations to prepare and dispense a homogenized die-bonding paste, in accordance with various examples of the present disclosure.

FIGS. 3A-3B illustrate a side, partial cut-away view of a sequence of operations related to placing a semiconductor chip placed on a suitable amount of homogenized die-bonding paste upon a substrate to form a semiconductor device, in accordance with various examples of the present disclosure.

FIG. 4A illustrates a top, plan view of a semiconductor device having a single semiconductor chip, in accordance with various examples of the present disclosure. FIG. 4B illustrates a side, plan view of the semiconductor device of FIG. 4A.

FIG. 5A illustrates a top, plan view of a semiconductor module having a plurality of semiconductor chips, in accordance with various examples of the present disclosure. FIG. 5B illustrates a side, plan view of the semiconductor module of FIG. 5A.

FIGS. 6A-6I illustrate a side, partial cut-away view of a sequence of operations related to molding a semiconductor module, in accordance with various examples of the present disclosure.

FIGS. 7A-7C illustrate a method of manufacturing a semiconductor module, in accordance with various examples of the present disclosure.

FIG. 8 illustrates a graph of experimental data related to die shear test force versus a condition of stirring times, in accordance with various examples of the present disclosure.

The drawing figures are intended to illustrate various features described herein which may not be drawn to scale.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

To be described in more detail below, semiconductor module can be implemented by one or more of a system, an apparatus, and a method described in accordance with the present disclosure. The described examples can efficiently and economically provide power dissipation and improved reliability for electronic systems that experience temperature excursions. As disclosed herein, examples of the disclosure provide various solutions related to operation and mounting of one or more semiconductor devices onto a substrate.

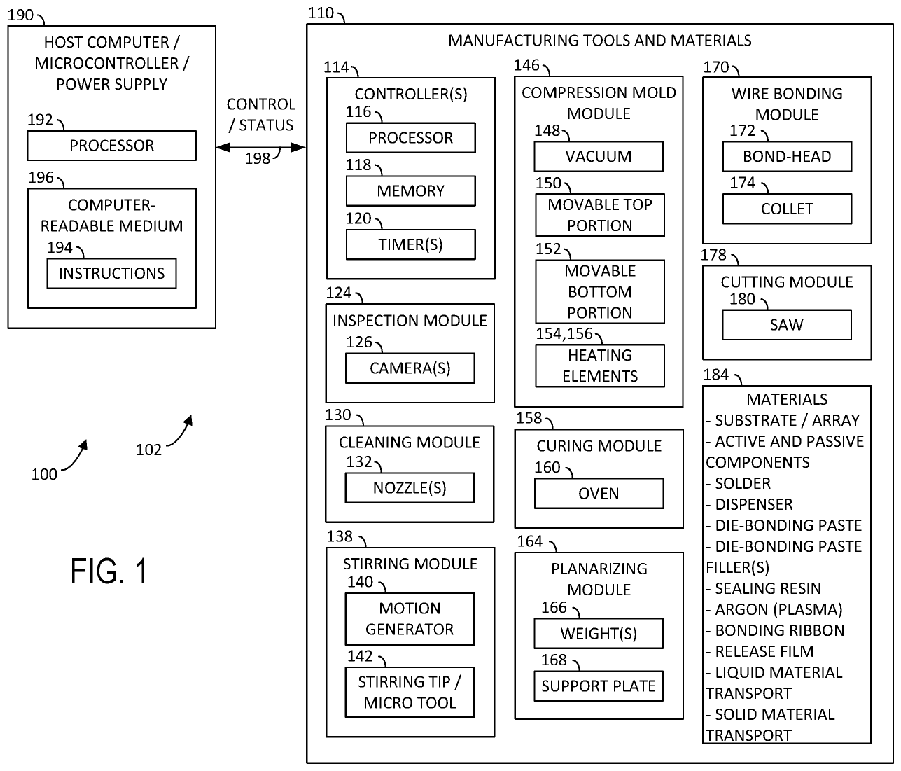

FIG. 1 illustrates a block diagram view showing details of a manufacturing system that can produce a semiconductor device, in accordance with various examples of the present disclosure. A semiconductor manufacturing system 100 may be implemented as a collection of various manufacturing devices 102 that employ various manufacturing tools and materials 110. For example, a manufacturing device 102 may include one or more interoperable elements of manufacturing tools and materials 110 to perform various operations and transformations of various materials and components to provide a semiconductor system, a semiconductor module, and various semiconductor devices, as disclosed herein. Semiconductor manufacturing system 100 may be implemented generally as a hybrid system including various electronic, mechanical, and electro-mechanical elements. Some or all of the various manufacturing devices 102 may be arranged within one or more enclosed chambers or cabinets to reduce process contamination and contain manufacturing byproducts such as gasses, noise, and the like.

In one example, manufacturing tools and materials may include a controller 114 with a processor 116 configured to read and execute instructions from a memory 118 to operate various manufacturing devices 102 in other computer accessible elements of semiconductor manufacturing system 100. Memory 118 (e.g., a non-transitory computer-readable medium) may containing instructions for controller 114 in the form of computer instructions (e.g., computer implemented code). Controller 114 may also implement a count-up and/or a count-down timer 120 (e.g., one or more serial or overlapping timers) that may be used to operate and control various processes corresponding to various methods described herein. Alternatively, timer 120 may be used to inform a user (e.g., using a display, an indicator light, or a sounder, not shown) regarding the status of a process such as a request to introduce or remove various materials and/or intermediate products into or from various manufacturing devices 102 composed of one or more interoperable elements of manufacturing tools and materials 110.

Manufacturing tools and materials 110 may include an inspection module 124 configured to inspect various items, including various components of a semiconductor device, a semiconductor module, and various elements associated with manufacturing tools and materials 110. Inspection module 124 may include one or more cameras 126 configured to inspect various components, including terminals, electrodes, substrates, semiconductor chip mounting surfaces, or to assist a user in inspecting various elements, and the like. Hence, inspection module 124 may be operated by controller 114 automatically or in cooperation with a user. Manufacturing tools and materials 110 may include a cleaning module 130 configured to clean various items, including various components of a semiconductor device, a semiconductor module, and various elements associated with manufacturing tools and materials 110. Cleaning module 130 may include one or more nozzles 132 configured to emit Argon gas (e.g., Argon plasma) to effectively clean various components, including terminals, electrodes, substrates, semiconductor chip mounting surfaces, and the like. Cleaning module 130 may be operated by controller 114 automatically or in cooperation with a user.

Manufacturing tools and materials 110 may include a stirring module 138 with a motion generator 140 configured to provide motion such as vibration to a stirring tip 142 (e.g., a micro tool) where motion generated from motion generator 140 is conducted through stirring tip 142 to stir or agitate a die-bonding (e.g., a die-attaching) paste, for example. Motion generator 140 may provide an oscillating motion to stirring tip 142 such as a high-speed or ultrasonic vibration at up to 40000 vibrations per minute (vpm), for example. Motion generator 140 may provide other oscillating motions at different frequencies, different amplitudes, and having different movement patterns, for example. Some portion or an entirety of motion generator 140 and stirring tip 142 may be hand-held and operated by a user. Further, stirring tip 142 may be an elongated member having a shank surrounded by threads or radial extensions in various sizes. For example, stirring tip 142 may have a shank with radial extensions disposed in a screw-like manner around the shank in order to agitate the die-bonding paste when actuated by motion generator 140.

Manufacturing tools and materials 110 may include a compression mold module 146 configured to perform compression molding of resin, as will be described more fully below. Compression mold module 146 may include a vacuum element 148, a movable top portion 150, a movable bottom portion 152, a first heating element 154, and a second heating element 156, as will be described more fully below. Alternatively, in some examples, second heating element 156 may not be used. Manufacturing tools and materials 110 may also include a curing module 158 with an oven 160, such as a heated cavity, for heating various elements such as substrates, components, and the like. Oven 160 may be used over an extended period according to a heating profile of increasing heat at a first rate to a first target temperature, sustaining heat at the first target temperature for a first predetermined heating time period, then decreasing heat at a second rate to a second target temperature for a second predetermined time period. In this manner, curing module 158 may be used to cure epoxy and/or resin placed in oven 160, for example. Manufacturing tools and materials 110 may also include a planarizing module 164 with one or more weights 166 and a support plate 168 configured to flatten a substrate or an array of substrates that may have developed a curvature from their original planar configuration due to various processing steps described herein such as curing.

Manufacturing tools and materials 110 may include a wire bonding module 170 configured to apply bonding wire to make electrical connections between various elements using a bond-head 172 and moving various components using a collet 174. Manufacturing tools and materials 110 may include a cutting module 178 with a saw 180 or other cutting device to cut and separate (e.g., to singulate) various semiconductor components, such as a plurality of assembled substrates or substrate array, for example. Finally, manufacturing tools and materials 110 may include a plurality of various materials 184 that may be used in the various manufacturing steps to be further elaborated below. For example, materials 184 may include one or more substrates, one or more active components such as semiconductor devices, one or more passive components such as resistors, capacitors, and inductors. Each of these passive or active components may be mounted to a substrate or other surfaces using various technologies, including surface mount technologies, for example. Materials 184 may include solder for flowing to connect various leads and wires. Materials 184 may include a dispenser (e.g., a syringe) for holding, mixing, homogenizing, and dispensing a die-bonding paste, for example.

Materials 184 may include sealing resin (e.g., a molding resin for compression molding) which is thermally conductive, but electrically insulative or non-conductive. Materials 184 may include a supply of Argon (Ar) gas for use with cleaning module 130. Materials 184 may also include a supply of bonding ribbon for use with wire bonding module 170. Materials 184 may also include a supply of release film for use with compression mold module 146. Finally, materials 184 may include various liquid transport tools and techniques to measure and dispense liquids within and for manufacturing tools and materials 110, such as liquid resin, and may also include various solid material transport technologies and techniques to measure and dispense various solid materials within and for manufacturing tools and materials 110, such as solid (e.g., granular) sealing resin and the release film, for example.

One or more computer accessible elements of manufacturing tools and materials 110 may be coupled with a host computer 190 which may include a processor 192 configured to read and execute instructions 194 from a memory 196 (e.g., a non-transitory computer-readable medium) which may contain instructions for host computer 190 in the form of computer instructions (e.g., computer implemented code). Host computer 190 may communicate with controller 114 over a control and status bus 198 to start and stop various operations, to update instructions in memory 118 of controller 114, to receive status regarding completion of various actions and various results, and the like.

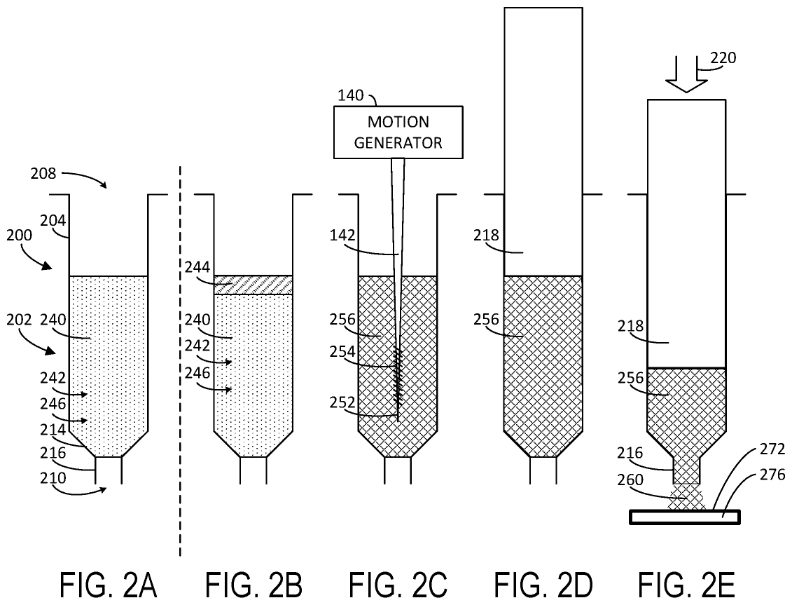

FIG. 2A-2E illustrate a side, partial cut-away view of a sequence of operations to prepare and dispense a homogenized die-bonding paste, in accordance with various examples of the present disclosure. FIG. 2A illustrates a partial cut-away view of a dispenser 200 that may be used for retaining a quantity of die-bonding paste 240. Dispenser 200 may be implemented as a syringe 202 having a graduated plastic or glass cylinder body 204 having a wide opening 208 and a narrow opening 210 on opposite ends of cylinder body 204. Syringe 202 may include a tapered portion 214 that narrows to a nozzle 216 (e.g., a hub 216) from which the contents of the syringe may be dispensed under compressive pressure from a piston 218 (e.g., a plunger, FIG. 2D) disposed in a portion of syringe 202 wide end 208 and advanced in a direction 220 (FIG. 2E) from wide end 208 toward narrow end 210. An angle of tapered portion 214 may not be critical. Nozzle 216 may be a cylindrical output portion that may be aligned centrally with a central axis of syringe 202, or nozzle 216 may be offset toward an outer edge of syringe body 204, for example.

The contents of syringe 202 may include a die-bonding paste 240, as mentioned briefly above. As a particular example, die-bonding paste 240 may be a silver-sintered (Ag) die-attaching (e.g., die-bonding) paste, having a mixture of silver and solvent-based resin in a defined ratio. Die-bonding paste 240 may have at least 80% or more silver content, and preferably may have about 87% silver content as a consequence of including a die-bond paste silver first filler 242 in the form of silver flakes or nuggets. Die-bonding material 240 may be purchased, transported, and stored in a frozen condition that is −40° C. or below, for example. Frozen die-bonding material 240 may be thawed or heated to about room temperature of around 25° C. (77° F.) prior to use to reduce viscosity and improve flow of die-bonding paste material 240 at a temperature which is well below a temperature where curing may begin to occur.

As illustrated in FIG. 2A, syringe 202 may be configured to receive thawed die-bonding paste material 240 (e.g., a silver-sintered epoxy paste) which includes a resin 246 and a first filler material 242 (e.g., a plurality of Ag/silver fillers) prior to freezing, storage, transportation, and thawing. Alternatively, syringe 202 may receive thawed or room temperature die-bonding paste material 240 which includes first filler material 242 and may be introduced through either wide end 208 or narrow end 210. As another alternative, a different die-bonding paste material without silver may be introduced into syringe 202 and an appropriate quantity of first filler material 242 may also be introduced into syringe 202. As illustrated in FIG. 2B, syringe 202 may be configured to receive thawed or room temperature die-bonding paste material 240 along with a second filler material 244 (e.g., a plurality of AlN/Aluminum Nitride fillers), for example. As before, the paste and/or fillers may be introduced separately or together through either wide end 208 or narrow end 210.

As illustrated in FIG. 2C, either the thawed preparation of die-bonding paste 240 including first filler 242 (Ag) in FIG. 2A or the thawed preparation of die-bonding paste 240 including first filler 242 in combination with second filler 244 (AlN) in FIG. 2B may be stirred to produce (e.g., to obtain) a homogenized die-bonding paste 256 in which first filler 242 and second filler 244 may be homogenously distributed throughout homogenized die-bonding paste 256. In one example, motion generator 140 may be operatively attached to stirring tip 142 and configured to impart a stirring or mixing motion to the contents of syringe 202 to produce homogenized die-bonding paste 256. Stirring tip 142 may include an end portion 252 configured to extend to a point (e.g., a suitable depth) within syringe 202 above tapered portion 214 where end portion 252 may be roughly equidistant from an interface between side portions of syringe 202 and a bottom portion of syringe 202 at an interface between tapered portion and nozzle 216, for example. In some examples, the interface between tapered portion 214 and nozzle 216 may be closed by a membrane or a stopper so that agitated die-bonding paste 256 may not escape from dispenser body 204 during stirring, for example. To improve mixing, stirring tip 142 may include a plurality of surfaces, such as threads or radial extensions in various sizes, which may extend radially from a long axis of stirring tip 142 and are configured to engage with die-boding paste 256 during stirring or mixing. Once the stirring is completed, the membrane (if present) may be pierced, or the stopper removed to allow passage of homogenized die-bonding paste 256 through nozzle 216.

As illustrated in FIG. 2C, stirring tip 142 may be inserted into wide end 208 to extend longitudinally through body 204. Alternatively, stirring tip 142 may be inserted a suitable distance into narrow end 210 into body 204. The stirring or mixing motion imparted by motion generator 140 to stirring tip 142 may persist for a predetermined period of time which is sufficient to homogenize die-bonding paste 240 along with first filler 242 and second filler 244, if used, so that the first filler 242 and the second filler 244 may be homogenously distributed throughout homogenized die-bonding paste 256. As described, first filler 242 and second filler 244 may be considered to be suspended in die-bonding paste 240 where the fillers are dispersed uniformly after stirring to produce homogenized die-bonding paste 256 as illustrated in FIG. 2D.

Once stirring is completed, motion generator and stirring tip 142 may be withdrawn from body 204 and piston 218 may be introduced into wide end 208, for example. Prior to dispensing homogenized die-bonding paste 256, a chip mounting surface 272 of a substrate 276 may be cleaned. Soon after stirring is completed (e.g., within about sixty minutes), the piston 218 may be advanced in a direction 220 from wide end 208 toward narrow end 210 and homogenized die-bonding paste 256 may be dispensed through nozzle 216 as a flow 260 onto a chip mounting surface 272 of a portion of a substrate 276, as illustrated in FIG. 2E. Thus, homogenized die-bonding paste 256 may have improved wettability for improving flow and contact with chip mounting surface 272 of substrate 276, and reduced dripping for reduced waste, spillage, and clean up. After dispensing a suitable amount of homogenized die-bond paste 256 onto chip mounting surface 272, a semiconductor chip (e.g., a semiconductor die) may be attached to chip mounting surface 272 via the homogenized die-bonding paste 256, as will be described more fully below. Homogenized die-bonding paste 256 may be dispensed and a semiconductor chip attached soon after stirring is completed to avoid settling (e.g., sedimentation) of homogenized die-boding paste 256, such as starting dispensing and attaching within a few seconds after stirring has finished and completing within a period of about sixty minutes, for example. Advantageously, the use of homogenized die-bonding paste 256 to attach a semiconductor chip to chip mounting surface 272, after curing, may reduce cracking and failure during thermal excursions and may also improve adhesion of the attached semiconductor chip, as will be described more fully below.

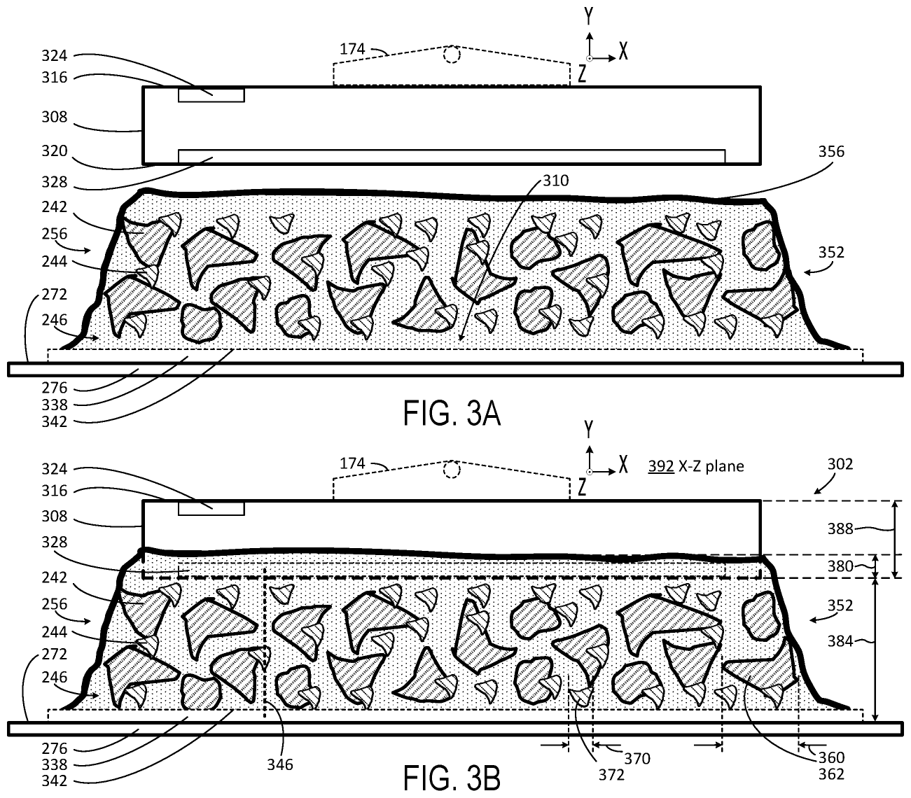

FIGS. 3A-3B illustrate a side, partial cut-away view of a sequence of operations related to placing a semiconductor chip placed on a suitable amount of homogenized die-bonding paste upon a substrate to form a semiconductor device, in accordance with various examples of the present disclosure. As illustrated in FIG. 3A, a semiconductor chip 308 may be carried by a wire bonding module 170 collet 174 (e.g., a die collet) that may be used to pick up and accurately place semiconductor chip 308 in a bonding region 310. As described in reference to FIGS. 2A-2E, semiconductor chip 308 may be attached to chip mounting surface 272 via the homogenized die-bonding paste 256. Homogenized die-bonding paste 256 may include filler materials such as larger and more dense silver (Ag) filler particles 242 along with smaller and less dense Aluminum Nitride (AlN) filler particles 244. For convenience, a semiconductor device 302 may be formed with one semiconductor chip 308, while a semiconductor module may be formed with two or more semiconductor chips, as will be described more fully below.

Semiconductor chip 308 may be formed of various technologies, including Gallium Nitride (GaN), Gallium Arsenide (GaAs), Silicon Carbide (SiC), Silicon On Insulator (SoI), Silicon (Si) Complementary Metal Oxide Semiconductor (CMOS), or other high temperature and/or high power dissipation microelectronics and semiconductor technologies. Semiconductor chip 308 may be an elongated structure that has a first side 316 (e.g., a front surface or a top side) and a second side 320 (e.g., a back surface or a bottom side) that is opposite the first side. Semiconductor chip 308 may include a first electrode 324 on first side 316 configured to electrically connecting to a circuit formed on or within semiconductor chip 308. Alternatively, first electrode 324 may be a conductive surface area of semiconductor chip 308 that is electrically connected to a circuit disposed at least partially within semiconductor chip 308. Electrodes may also be denoted as electrical conductors or pads, and may be a location for wire bonding, and the like, for connecting semiconductor chip 308 to another electrical system, for example. Similarly, semiconductor chip 308 may include a second electrode 328 on a second side 320 configured to electrically connect to the same or a different circuit formed on semiconductor chip 308. In this manner, first electrode 324 and second electrode 328 may be disposed on opposite sides of semiconductor chip 308. Second electrode 328 may be co-planar with bottom surface 320 of semiconductor chip 308. Chip mounting surface 272 may include an optional terminal 338 that is electrically connected to a portion of the chip mounting surface 272 or to another circuit associated with substrate 276. Terminal 338 may have a top surface 342 that is electrically conductive. In another example, top surface 342 may be co-planar with chip mounting surface 272.

As described in reference to FIGS. 2A-2E above, a suitable amount 352 of homogenized die-bonding paste 256 may be deposited upon a cleaned chip mounting surface 272 with improved wettability and reduced dripping. In particular, as shown in FIG. 2E, a measured amount 352 of homogenized die-bonding paste 256 may be deposited in at least five portions, one portion for each corner of the placed semiconductor chip and at least one portion in the center between the corners. For an elongated, rectangular semiconductor chip, additional portions may be deposited upon a long axis of the semiconductor chip placement. Once a suitable amount 352 of homogenized die-bonding paste 256 is deposited in a bonding region 310, as illustrated in FIG. 3B, semiconductor chip 308 may be placed by wire bonding module collet 174 upon a top surface 356 of die-bonding paste 256 at a depth 380 where entire bottom surface 320 of semiconductor chip 308, including second electrode 328, is immersed within a portion of suitable amount 352 of die-bonding paste 256 to form a semiconductor device 302. A suitable amount 352 of homogenized die-bonding paste may be based upon the rectangular size of the semiconductor chip (e.g., semiconductor die) that is sufficient to cover the entire bottom surface 320 of semiconductor chip 308 and a portion of each of the sides of the semiconductor chip, as described. Bottom surface 320 may be separated from chip mounting surface 272 by a distance 384 which may be at least 1.0 mils (0.001 inches, 25.4 micrometers) and not more than 1.5 mils (0.0015 inches, 38.1 micrometers) from chip mounting surface 272, and may preferably be about 1.25 mils (0.0012 inches, 31.8 micrometers). In one example, depth 380 may correspond to about 15-20 percent (15-20%) of a thickness 388 (about 110 micrometers) of semiconductor chip 308.

After semiconductor chip 308 is positioned as described above, an electrical conduction path 346 may be formed between second electrode 328 and terminal 338 through suitable amount 352 of homogenized die-bonding paste 256. Terminal 338 may span an entire width (as shown in FIG. 3A) of homogenized die-bonding paste 256 between bottom portion 320 of semiconductor chip 308, or terminal 338 may span only a portion of this width while extending underneath a portion of bottom portion 320, for example. In this manner, homogenized die-bonding paste 256 may connect between bottom portion 320 of semiconductor chip 308 and both terminal 338 and surface 272 of substrate 276. Electrical conduction path 346 may be a primary or supplemental grounding path, for example, or an electrical signal path. In this manner, suitable amount 352 of homogenized die-bonding paste may be both thermally and electrically conductive both before and after curing. Semiconductor chip 308 may be placed upon suitable amount 352 of homogenized die-bonding paste 256 and oriented so that bottom surface 320 is substantially parallel with chip mounting surface 272 within tolerances so that tilt relative to an X-Z plane 392 is about 2 micrometers (about 2 um, 7.87E−5 inches) or less on all four sides of semiconductor chip 308 relative to chip mounting surface 272, for example. These tolerances may reflect a die attach process consistency (Cpk) that is greater than 1.33 compared with specification requirements over time, for example.

Die-bond paste first filler 242 in the exemplary die-bond paste may have an average diameter 360 of about 1 micrometer (about 1 um, 3.94E−5 inches) and a density 362 of about 10.49 g/cm³ (e.g., per unit volume, or by using a unit volume). In some examples, an appropriate quantity of a second filler 244 may be introduced into syringe 202 wide end 208 such as Aluminum Nitride (AlN) in the form of flakes or nuggets having an average diameter 370 of about 250 nanometers (about 250 nm, 9.84E−6 inches) and a density 372 of about 3.26 g/cm³ (e.g., per unit volume) and available widely through chemical supply vendors. In this example, a ratio between a first filler 242 density 362 and a second filler 244 density 372 (e.g., first density 362 divided by second density 372) may be greater than 3-times to help maintain homogeneity after stirring (or mixing). Once one or more semiconductor chips are placed upon suitable amount 352 of homogenized die-bonding paste 256 and oriented so that bottom surface 320 is substantially parallel with chip mounting surface 272, substrate 276 carrying the one or more mounted semiconductor chips may be passed to a curing module 158 having a curing oven 160 to provide an elevated temperate for an extended time according to a thermal curing profile, based on the selected die-bonding paste 240. For example, when using homogenized die-bonding paste 256, substrate 276 with one or more semiconductor chips mounted via a suitable amount 352 of homogenized die-bonding paste 256 may be placed in oven 160 that is activated at a first target temperature of about 200° C. (392° F.) with a ramp up time of sixty minutes to achieve the first target temperature followed by a cure time of about another sixty minutes holding at 200° C. to fully cure homogenized die-bonding paste 256, for one example.

Alternatively, oven 160 may be activated at a second target temperature of about 175° C. (347° F.) with a ramp up time of sixty minutes to achieve the second target temperature followed by a cure time of about another ninety minutes holding at 175° C. to fully cure homogenized die-bonding paste 256, for another example. In this manner, a mixture of silver and solvent may create a permanent bridge between filler molecules (242, 244) after cure. Thus, forming a thermal and electrical conducting path. Other curing temperature profiles may be possible.

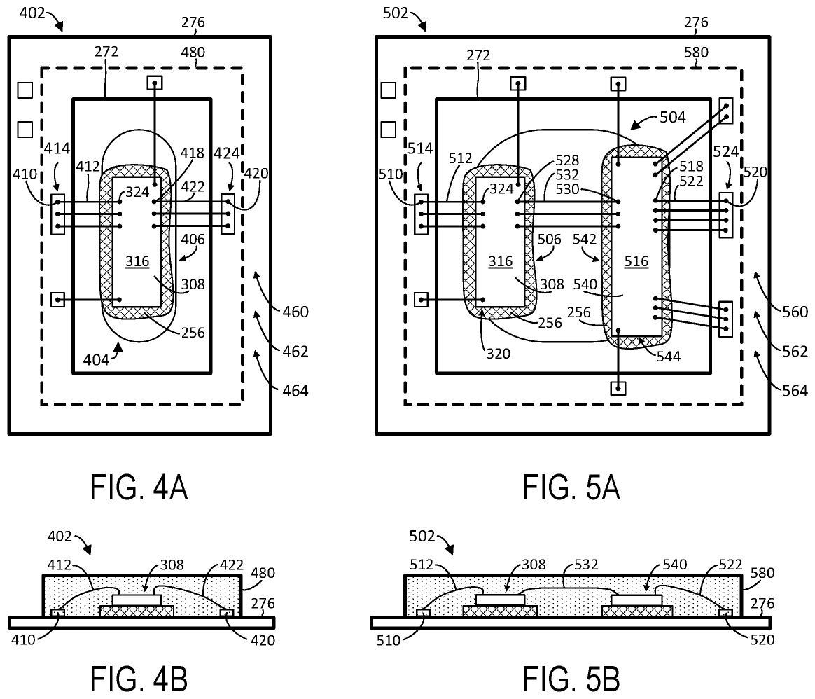

FIG. 4A illustrates a top, plan view of a semiconductor device having a single semiconductor chip, in accordance with various examples of the present disclosure. As illustrated, semiconductor device 402 may include a semiconductor chip 308. Semiconductor chip 308 may be similar in some ways to semiconductor chip 308 described in reference to FIGS. 3A-3B. After cleaning a chip mounting surface 272 including a first bonding region 406, semiconductor chip 308 may be placed on a chip mounting surface 272 of substrate 276 via a suitable amount 352 of homogenized die-bonding paste 256 supplied onto bonding region 406. A suitable amount of homogenized die-bonding paste 256 may be based upon the rectangular size of semiconductor chip 308 (e.g., semiconductor die). Each suitable amount of homogenized die-bonding paste 256 may be sufficient to cover an entire bottom surface 320 of first semiconductor chip 308 along with a suitable portion of each of the sides of semiconductor chip 308 and support semiconductor chip 308 at a height above substrate 276 (e.g., separation distance from substrate 276), as described in reference to FIGS. 3A-3B, for example.

After curing of homogenized die-bonding paste 256, electrical connections may be made with the placed semiconductor chip, as needed. Semiconductor chip 308 may include a top surface 316 having a plurality of electrodes, for example. Wire bonding module 170 may provide wired connections by applying a suitable length of bonding ribbon segments between electrodes, terminals, or other electrical connectors available on semiconductor device 402. Wire bonding module 170 may apply a first bonding ribbon segment between electrode 324 on semiconductor chip 308 and a terminal 410 as a first wire 412, for example. Each bonding ribbon segment may be considered a wire, such as wire 412, and may conduct an electrical signal or electrical power. Terminal 410 may include a surface 414 that is cleaned along with other surfaces after curing and before activating wire bonding module 170 to ensure formation of a reliable electrical and structurally durable connection. Both electrode 324 and terminal 410 may be positioned at different heights relative to each other when compared with chip mounting surface 272 or substrate 276 (e.g., a floor). Terminal 410, and other terminals, may be an electrical connector or a pad (e.g., an electrode) mounted on substrate 276, so terminals may be a contact that may extends from substrate 276 or may be co-planar with a top surface of substrate 276, while electrode 324 may be positioned on a top surface of semiconductor chip 308, for example.

Wire bonding module 170 may be programmed to include a loop of a predetermined height at each bonding location, so that the bonding wire between electrode 324 and terminal 410 may have a height profile, for example. A bonding wire with a higher loop may be less reliable due to greater susceptibility to possible detachment under various conditions, such as vibration of substrate 276 which may be conducted to each of the unreinforced, or movement of unsupported bonding wires. Thus, each wire formed by wire bonding module 170 may have various dimensional characteristics, including height, lateral shift in die attach location, loop direction, and other features. Wire bonding module 170 may apply a second bonding ribbon segment between electrode 418 on semiconductor chip 308 and a terminal 420 as a second wire 422, for example. Terminal 420 may include a surface 424 that is cleaned along with other surfaces after curing and before activating wire bonding module 170 to ensure formation of a reliable electrical and structurally durable connection. First wire 412 and second wire 422 are exemplary in nature. Other electrical signal or electrical power wires to and between the plurality of semiconductor chips and various terminals or connectors in semiconductor device 402 may be formed in a similar manner.

After curing and wire bonding are completed, a thermally conductive sealing resin 480 may be formed over semiconductor chip 308 and various terminals in order to seal, encapsulate, protect, and conduct heat away from semiconductor chip 308 as well as conduct heat within a region of chip mounting surface 272 and substrate 276 covered by sealing resin 480. Substrate 276 may include a wiring substrate 460 (e.g., or a lead frame or ceramic substrate), a glass fiber 462, and/or an epoxy resin 464. In general, a semiconductor device with a substrate upon which only one semiconductor chip is mounted and cured may be less likely to experience warpage compared with a substrate upon which two or more semiconductor chips are mounted and cured, as described. In some situations, it may be desirable to flatten substrate 276 of semiconductor device 402 after curing to resolve any possible warpage, with or without inspection. FIG. 4B illustrates a side, plan view of the semiconductor device of FIG. 4A. In this illustration, various exemplary features may be shown about how sealing resin 480 may surround semiconductor chip 308, first wire 512, and second wire 522, for example.

FIG. 5A illustrates a top, plan view of a semiconductor module having a plurality of semiconductor chips, in accordance with various examples of the present disclosure. As illustrated, semiconductor module 502 may include a first semiconductor chip 308 and a second semiconductor ship 540. First semiconductor chip 308 may be similar in some ways to semiconductor chip 308 described in reference to FIGS. 3A-3B and FIGS. 4A-4B. For example, first semiconductor chip 308 may comprise of one of GaN or GaAs technologies, while second semiconductor chip 540 may be formed of Si technologies, or vice versa. Alternatively, each semiconductor chip performing a particular function may comprise the same technology, such as four GaN power amplifier chips mounted on substrate 276, for example. After cleaning a chip mounting surface 272 including a first bonding region 506 and a second bonding region 542, first semiconductor chip 308 may be placed on a chip mounting surface 272 of substrate 276 via a suitable amount 352 of homogenized die-bonding paste 256 supplied onto first bonding region 506. Similarly, second semiconductor chip 540 may be placed on a chip mounting surface 272 of substrate 276 via a suitable amount 352 of homogenized die-bonding paste 256 suppled onto second bonding region 542. For each of the placed semiconductor chips, a suitable amount of homogenized die-bonding paste may be based upon the rectangular size of the semiconductor chip (e.g., semiconductor die). Each suitable amount of homogenized die-bonding paste 256 may be sufficient to cover an entire bottom surface 320 of first semiconductor chip 308 and an entire bottom surface 544 of second semiconductor chip 540, for example, along with a suitable portion of each of the sides of the semiconductor chips and support each of the semiconductor chips at a height above substrate 276 (e.g., separation distance from substrate 276), as described in reference to FIGS. 3A-3B, for example.

After curing of homogenized die-bonding paste 256, electrical connections may be made with and between each of the placed semiconductor chips, as needed. First semiconductor chip 308 may include a top surface 316 having a plurality of electrodes, and second semiconductor chip 540 may have a top surface 516 having a plurality of electrodes, for example. Wire bonding module 170 may provide wired connections by applying a suitable length of bonding ribbon segments between electrodes, terminals, or other electrical connectors available on semiconductor module 502. Wire bonding module 170 may apply a first bonding ribbon segment between electrode 324 on first semiconductor chip 308 and a terminal 510 as a first wire 512, for example. Each bonding ribbon segment may be considered a wire, such as wire 512, and may conduct an electrical signal or electrical power. Terminal 510 may include a surface 514 that is cleaned along with other surfaces after curing and before activating wire bonding module 170 to ensure formation of a reliable and structurally durable connection. Both electrode 324 and terminal 510 may be positioned at different heights relative to each other when compared with chip mounting surface 272 or substrate 276 (e.g., a floor). Terminal 510, and other terminals, may be an electrical connector or a pad (e.g., an electrode) mounted on substrate 276, so terminals may extend from substrate 276 or may be co-planar with a top surface of substrate 276, while electrode 324 may be positioned on a top surface of first semiconductor chip 308, for example.

Wire bonding module 170 may be programmed to include a loop of a predetermined height at the bonding location, so that the bonding wire between electrode 324 and terminal 510 may have a height profile for each bonding wire, for example. A bonding wire with a higher loop may be less reliable due to greater susceptibility to possible detachment under various conditions, such as vibration of substrate 276 which may be conducted to each of the unreinforced, or unsupported bonding wires. Thus, each interconnection wire formed by wire bonding module 170 may have various dimensional characteristics, including height, lateral shift in die attach location, loop direction, and other features. Wire bonding module 170 may apply a second bonding ribbon segment between electrode 518 on second semiconductor chip 540 and a terminal 520 as a second wire 522, for example. Terminal 520 may include a surface 524 that is cleaned along with other surfaces after curing and before activating wire bonding module 170 to ensure formation of a reliable and structurally durable connection. Similarly, wire bonding module 170 may apply a third bonding ribbon segment between electrode 528 on first semiconductor device 308 and electrode 530 on second semiconductor chip 540 as a third wire 532. First wire 512, second wire 522, and third wire 532 are exemplary in nature. Other electrical signal wires or electrical power wires to and between the plurality of semiconductor chips and various terminals or connectors in semiconductor module 502 may be formed in a similar manner.

After curing and wire bonding are completed, a thermally conductive sealing resin 580 may be formed over first semiconductor chip 308, second semiconductor chip 540, and various terminals in order to seal, encapsulate, protect, and conduct dissipated heat away from first semiconductor chip 308, second semiconductor chip 540, and heat conducted within a region of chip mounting surface 272 and substrate 276 covered by sealing resin 580. Substrate 276 may include a wiring substrate 560 with a glass fiber 562, and an epoxy resin 564. In general, a semiconductor module with a substrate upon which two or more semiconductor chips may be mounted and cured may be more likely to experience warpage compared with a substrate upon which one semiconductor chip is mounted and cured, as described. In some situations, it may be desirable to flatten substrate 276 of semiconductor module 502 after curing to resolve any possible warpage, with or without inspection. FIG. 5B illustrates a side, plan view of the semiconductor module of FIG. 5A. In this illustration, various exemplary features may be shown about how sealing resin 580 may surround each of first semiconductor chip 308, second semiconductor chip 540, first wire 512, second wire 522, and third wire 532.

Various configurations of semiconductor chips in semiconductor module 502 are possible. For example, semiconductor module 502 may also include four semiconductor chips where each semiconductor chip is formed as a Gallium Nitride (GaN) power amplifier (PA), and together the four-semiconductor chip GaN semiconductor module 502 may be a multi-chip module power amplifier. As the number of semiconductor chips in semiconductor module 502 increases, the likelihood of substrate 276 warpage may also increase.

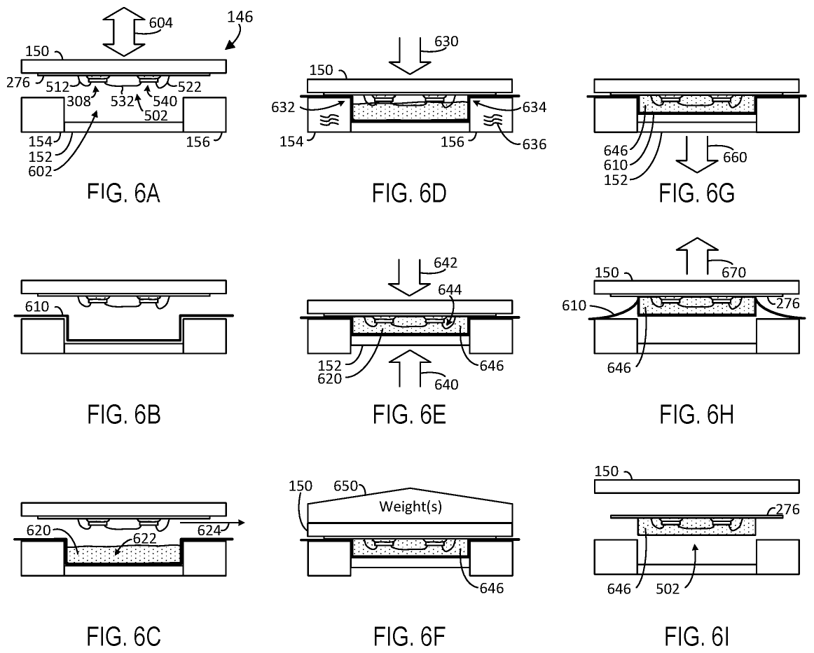

FIGS. 6A-6I illustrate a side, partial cut-away view of a sequence of operations related to molding a semiconductor module, in accordance with various examples of the present disclosure. In continuing reference to FIG. 1 and FIGS. 5A-5B, FIG. 6A illustrates a beginning step of a compression molding method utilizing a compression molding module 146 that may have a movable top portion 150, a movable bottom portion 152, a first heating element 154 disposed on a left-side of compression mold module 146, as illustrated, and a second heating element 156 disposed on a right-side of compression mold module 146, as illustrated, to form a compression mold cavity 602 that may have an open and a closed position. In some examples, only one heating element may be used, where the only one heating element may be disposed on one side of compression mold cavity 602, but not both. An exemplary semiconductor module 502 may be mounted on an underside portion of movable top portion 150, where a top surface of semiconductor module 502 is directed downward into mold cavity 602. In this manner, movable top portion 150 may be moved in a downward and upward direction 604, as illustrated, so that the mounted semiconductor module 502 may be moved into and out of compression mold cavity, for example.

FIG. 6B illustrates an intermediate step of a compression mold process, where a portion of a release film 610 from materials 184 may be placed over portions of compression mold module 146 to enable release of a mold product from compression mold module 146. Release film 610 may be a temperature resistant film that may also be configured to retain a suitable quantity of sealing resin in granular or liquid form and when the sealing resin is heated over a period of time. Release film 610 may be partially compressible to form a pressure seal, as will be described more fully below.

FIG. 6C illustrates an intermediate step of a compression mold process, where a quantity of sealing resin 620 from materials 184 may be placed in a reservoir 622, a bowl, or a tank portion defined by release film 610 for retaining sealing resin 620 in a solid, heated liquid, then solid form. While shown in partial cut away form, it is understood that the reservoir 622 extends in three dimensions, and release film 610 surrounds reservoir 622 in a front, back, left side, right side, and bottom, as illustrated. A vacuum 148 may be activated in order to evacuate 624 air and other gasses from reservoir 622.

FIG. 6D illustrates an intermediate step of a compression mold processes, where movable top portion 150 may be moved in a downward direction 630 to close compression mold module 146 once vacuum 148 has evacuated air, airborne contaminants, and possibly other gases from reservoir 622. Edge portions of release film 610 may be positioned between substrate 276 and top portions of left heating element 154, right heating element 156, a front wall, and a back wall of reservoir 622 to retain sealing resin 620, for example. Front wall and back wall are not shown in this view. Edge portions of release film 610 may be compressed around a top edge portion of sealing resin reservoir 622 illustrated by a left edge 632 and a right edge 634. Front edge and back edge of the top edge seal are not shown in this view. Left heating element 154 and/or right heating element 156 may be activated 636 to melt sealing resin 620 to a molten state (e.g., fully and uniformly melted).

FIG. 6E illustrates an intermediate step of a compression mold processes, where movable bottom portion 152 may be moved in an upward direction 640 to provide compression of molten sealing resin 620 in reservoir 622 against a top surface of semiconductor module 502, causing compression mold module 146 to immerse a top surface of semiconductor module 502 including first semiconductor 308, second semiconductor 540, and various bonding wires (512, 522, 532) to reach a top surface of substrate 276, for example, in the molten sealing resin. While movable bottom portion 152 may be urged in an upward direction, movable top portion 150 may be urged in a downward direction 642. Minimal compressive force may be needed to make a proper seal around a top portion of reservoir 622 and to ensure any remaining compressible air does not molten sealing resin from fully covering all exposed surfaces of substrate 276 facing downward into reservoir 622, as illustrated. It is noted that a quantity of sealing resin is sufficient to ensure the highest wire bond loop is fully immersed in molten sealing resin without touching (e.g., without compressing) any wire bond loops 644. In this example, once sealing resin 620 is in a molten state and compression mold module 146 is closed, substrate 276 carrying semiconductor module 502 may be immersed in molten sealing resin 620 and may be a molded package 646 (e.g., a sealing body 646) that may be clamped between movable top portion 150 as a first metal plate and clamped between moveable bottom portion 152 as a second metal plate. Once molded package 646 is clamped, oven 160 may be activated according to a curing profile to cure sealing resin 620 over a predetermined period of time. Once, compression mold module 146 is closed and sufficient compression is applied to molten sealing resin 620, left heating element 154 and right heating element 156 (if both are used) may both be deactivated so molten resin 620 may now proceed toward cooling, solidification, and curing as molded package 646. Other curing profiles may be used which depend on the curing properties of the selected sealing resin 620, for example.

FIG. 6F illustrates an optional intermediate step of a compression mold processes, where one or more weights 650 may be placed on top of movable top portion 150 while sealing resin 620 cures and then cools as molded package 646. In reference briefly to FIG. 1, FIG. 6F may illustrate a post mold curing (PMC) step following a compression molding process implemented by a planarizing module 164 having one or more weights 166. For example, weight 650 may be a 1 kg weight placed on top of moveable top portion 150 for stress relief. Oven 160 may be activated at a first target temperature of about 175° C. (347° F.) with a ramp up time of about fifteen to thirty minutes to achieve the target temperature, a cure time of about four hours during which time the sealing resin 620 may fully cure. After this, oven 160 may be set to a second target temperate of about 25° C. (77° F.) and a ramp down time of about thirty minutes to achieve the second target temperature after which the substrate 276 and cured sealing resin 620 may proceed to the next step. Other temperature profiles may be used.

FIG. 6G illustrates an intermediate step of a compression mold processes, where sealing resin 620 may be fully cured and cooled, and compression mold module 146 may begin to open by moving movable bottom portion 152 in a downward direction 660 to release movable bottom portion 152 from release film 610. Further, FIG. 6H illustrates an intermediate step of a compression mold process, where movable top portion 150 may be moved in an upward direction 670 to extract substrate 276 with cured sealing resin 620 encapsulating semiconductor module 502 from compression mold module 146. Outer portions of release film 610 may droop and become easier to access or grasp, making release film easier to remove. Finally, FIG. 6I illustrates a final step of removing release film 610 and separating substrate 276 from movable top portion 150, when curing and planarizing of substrate 276 may be complete. Substrate 276 may be part of an array of substrates that may be separated from each other in a singulation process, by passing the array of substrates to a cutting module 178 having a saw 180 or other, suitable cutting device, for example.

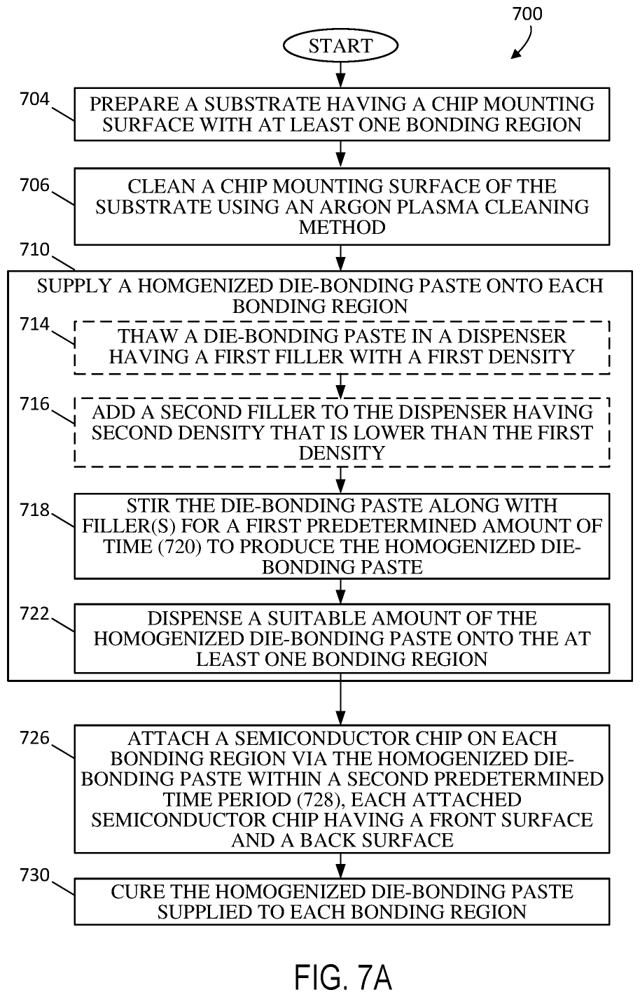

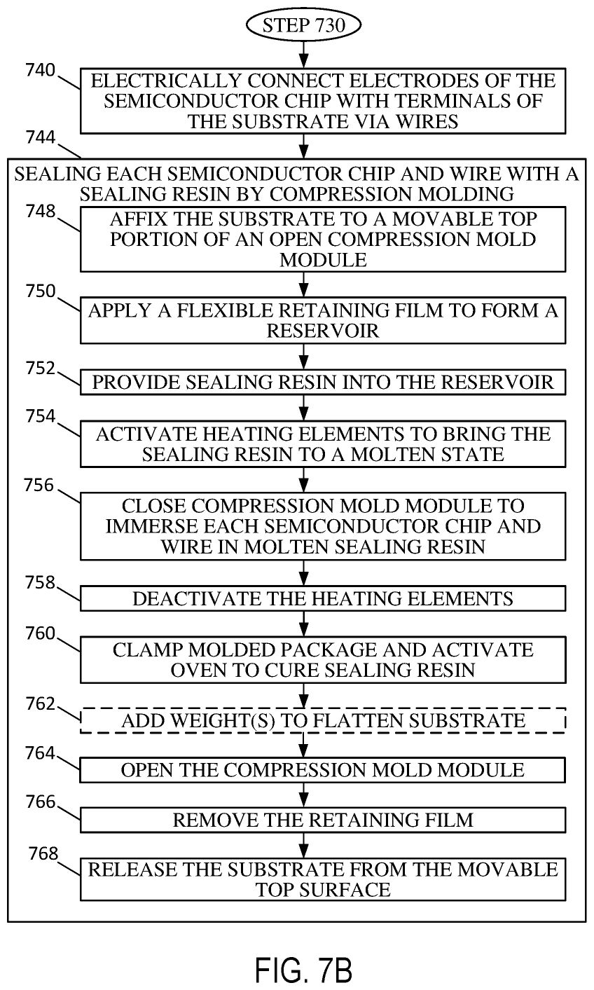

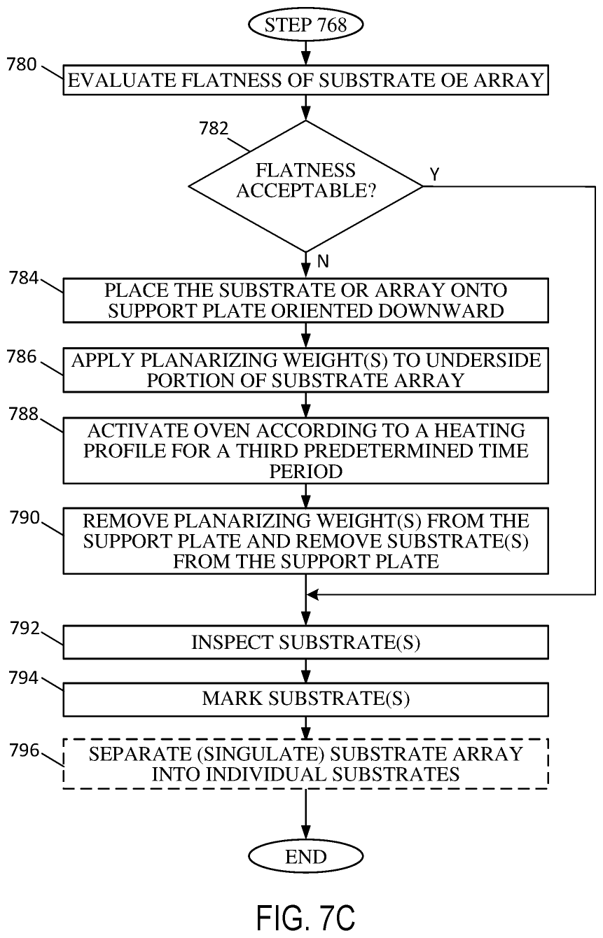

FIGS. 7A-7C illustrate a method of manufacturing a semiconductor module, in accordance with various examples of the present disclosure. FIGS. 7A illustrates a method 700 of manufacturing (e.g., obtaining) a semiconductor device 402 and a method of manufacturing a semiconductor module 502. In reference to FIG. 1 through FIG. 7C, method 700 may begin with step 704 of preparing a substrate 276 having chip mounting surface 272 with at least one bonding region. In this manner, step 704 may include preparing substrate 276 having chip mounting surface 272 and a first bonding region 506 and a second bonding region 542. In this example, preparing a substrate 276 may include a coarse cleaning process and arranging substrate 276 and necessary components and/or materials 184 in an initial setup. Method 700 may proceed with step 706 of cleaning (e.g., fine cleaning) a chip mounting surface 272 of substrate 276 using an argon (Ar) plasma cleaning method. In this process, argon gas plasma is emitted in proximity to chip mounting surface 272 to remove debris without etching chip mounting surface 272, to remove electrostatic charges on chip mounting surface 272, and to clean chip mounting surface 272 without leaving a residue. In this example, various terminals and connectors may also be cleaned with the argon plasma cleaning method.

Method 700 may proceed with step 710 of supplying a homogenized die-bonding paste 256 onto chip mounting surface 272 and each bonding region. In this example, step 710 may include supplying a suitable amount 352 of homogenized die-bonding paste 256 to each of first bonding region 506 and second bonding region 542. Method 700 step 710 of supplying may include various sub-steps, including an optional sub-step 714 of thawing a frozen die-bonding paste 240 in a dispenser 200 which may include a plurality of first fillers 242 including silver (Ag) having a first density 362. Dispenser 200 may be a syringe 202, for example. Sub-step 714 of thawing may be optional because die-bonding paste 240 may not be frozen, may not be initially located inside dispenser 200 (e.g., syringe 202), or may not have first fillers 242 already within die-bonding paste 240 in some situations. In this case, die-bonding paste 240 may be added to dispenser 200 along with adding first fillers 242. Step 710 of supplying may proceed with optional sub-step 716 of adding a second filler 244 including aluminum nitride (AlN) having a second density 372 to dispenser 200. Step 710 of supplying may proceed with sub-step 718 of stirring the unstirred die-bonding paste 240, along with first filler 242 and possibly second filler 244, for a first predetermined time period 720 (e.g., a first predetermined amount of time), which may be at least ninety (e.g., 90) seconds and not more than 150 seconds, for example, to produce (e.g., to obtain) homogenized die-bonding paste 256. In this manner, homogenized die-bonding paste 256 is initially provided as an unstirred die-bonding paste 240 including a plurality of Ag fillers 242. Step 710 of supplying may conclude with a sub-step 722 of dispensing a suitable amount 352 of homogenized die-bonding paste 256 onto chip mounting surface 272 having at least one bonding region. In this example, sub-step 722 may include dispensing suitable amount 352 of homogenized die-bonding paste 256 onto at least one of first bonding region 506 and second bonding region 542.

After step 710 of supplying, method 700 may proceed with step 726 of attaching a semiconductor chip on each bonding region via a suitable mount 352 of homogenized die-bonding paste 256, where each semiconductor chip has a front surface and a back surface opposite the front surface. In this example, step 726 may include attaching first semiconductor chip 308 on first bonding region 506 via homogenized die-bonding paste 256 supplied onto first bonding region 256 within a second predetermined time period 728 (e.g., and first semiconductor chip 308 attached within about sixty minutes), where first semiconductor chip 308 may have a first front surface 316, a first back surface 320 opposite first front surface 316, and a first electrode 324 formed on the first front surface. In this example, step 726 may also include attaching second semiconductor chip 540 on second bonding region 542 via homogenized die-bonding paste 256 supplied onto second bonding region 542 within second predetermined time period 728, where second semiconductor chip 540 may have a second front surface 516, a second back surface 544 opposite second front surface 516, and a second electrode 518 formed on the second front surface. Method 700 may continue with step 730 of curing homogenized die-bonding paste 256 supplied to each bonding region. In this example, step 730 may include curing suitable amount 352 of homogenized die-bonding paste 256 supplied to each of first bonding region 506 and second bonding region 542. In this manner, the cured die-bonding paste 256 may include a plurality of AG fillers 242 and may further include a plurality of AlN fillers 244. During the curing process, solvent-based resin 246 may be evaporated.

As illustrated in FIG. 7B, method 700 may continue with step 740 of electrically connecting first electrode 324 of first semiconductor chip 308 with a first terminal 510 of substrate 276 via a first wire 512, and electrically connecting second electrode 518 of second semiconductor chip 540 with a second terminal 520 of substrate 276 via a second wire 522. Further, step 740 may include connecting a third electrode 528 of first semiconductor ship 308 with a fourth electrode 530 of second semiconductor chip 540 via a third wire 532. As described, wire bonding module 170 may electrically connect various terminals on substrate 276 with various electrodes (e.g., pads) on semiconductor chips using bonding ribbon as wires, and may electrically connect various electrodes on semiconductor chips together with other semiconductor chips with bonding ribbon as wires.

Once all electrical connections formed with wire bonding module 170 are completed, method 700 may continue with step 744 of sealing each of the semiconductor chips and wires with a sealing resin 620 by compression molding, as described in reference to FIG. 6A-6I. In one example, method 700 may continue with step 744 of sealing first semiconductor chip 308, second semiconductor chip 540, first wire 512, and second wire 522 with sealing resin 620 by compression molding. Method 700 step 744 of sealing may include various sub-steps, including sub-step 748 of affixing substrate 276 to a movable top portion 150 of an open compression mold module 146. Step 744 may continue with sub-step 750 of applying a flexible retaining film to form a reservoir 622. Step 744 may continue with sub-step 752 of providing a suitable quantity of sealing resin into reservoir 622. Step 744 may continue with sub-step 754 of activating heating elements 154, 156 to bring sealing resin 620 to a molten state. Step 744 may continue with sub-step 756 of closing compression mold module 146 to immerse each semiconductor chip and wire in molten sealing resin 620.

Once sealing resin 620 is in a molten state and compression mold module 146 is closed, step 744 may continue with sub-step 758 of deactivating heating elements 154, 156. Step 744 may continue with sub-step 760 of clamping molded package 646 between movable top portion 150 (e.g., a first metal plate) and movable bottom portion 152 (e.g., a second metal plate) and activating oven 160 to heat molded package 646 to cure sealing resin 620 according to a heating profile depending on the selected sealing resin 620, for example. Step 744 may continue with optional sub-step 762 of adding one or more weights to flatten substrate 276 while molded package 646 is curing. Step 744 may continue with sub-step 764 of opening compression mold module 146. Step 744 may continue with sub-step 766 of removing retaining film 610. Step 744 may conclude with sub-step 768 of releasing substrate 276 carrying molded package 646 from movable top surface 150. In one example, molded package 646 may be associated with a single substrate 276 that was previously separated from other substrates in an array of substrates, in materials 184. In other examples, molded package 646 may be associated with a substrate that is attached with other substrates in an array of substrates in materials 184, and where each associated substrate is detached (e.g., singulated, separated) after compression molding and curing is completed.

After sealing each semiconductor chip and wire with a sealing resin by compression molding in step 744, method 700 may continue in step 780 of evaluating flatness of a substrate 276 or an array of substrates, as described above. For example, inspection module 124 and one or more cameras 126 may be used to inspect substrate array and compare with a known flat edge tool, utilize one or more feeler gauges, or other devices. Method 700 may continue with step 782 of determining whether the flatness of substrate array is acceptable, or not. If the flatness of the substrate array is not acceptable, method 700 may continue with step 784 of placing substrate 276 or array of substrates onto support plate 168 in a face-down manner (e.g., the cured portion downwardly oriented). For example, support plate 168 may have a raised border for surrounding substrate 276 or array of substrates so that a top surface of a downwardly oriented substrate may be flat with the border, if the substrate is flat. However, curing may cause curvature in a direction towards the cured surface, in some circumstances. An unacceptably flat substrate 276 may extend up (e.g., curve upward) from the border of support plate 168.

Method 700 may continue with step 786 of applying one or more plates or planar weights 166 from planarizing module 164 to an underside portion of substrate 276 which may protrude above the border of support plate 168. Weights 166 may be 0.5 kg (1.1 pounds), 1.0 kg (2.2 pounds), or 1.5 kg (3.3 pounds) alone or in combination depending on the amount and rate of flattening that may be needed, for example. Method 700 may continue with step 788 of activating oven 160 according to a heating profile for a third predetermined amount of time. For example, oven 160 may be activated at a third target temperature of about 175° C. (347° F.) with a ramp up time of about fifteen to thirty minutes to achieve the target temperature, followed by a soaking time of about seven hours during which time substrate 276, or array of substrates, may be planarized or flattened. After this, oven 160 may be set to a fourth target temperate of about 25° C. (77° F.) and a ramp down time of about thirty minutes to achieve the fourth target temperature after which the substrate 276 may be flattened. Method 700 may continue with step 790 of removing planarizing weights from above support plate 168 and removing substrate 276, or array of substrates, from support plate 168. Method 700 may continue with the step 792 of inspecting substrate 276, or array of substrates. After step 780 of evaluating, if flatness of substrate 276, or array of substrates, is acceptable, control may move to step 792, to avoid post mold cure flattening, as described. Method 700 may continue with step 794 of marking substrate 276, or each substrate in an array of substrates, to indicate various properties of each substrate. Following this, method 700 may conclude with an optional step 796 of separating (e.g., singulating) an array of substrates into individual, marked substrates, as needed.

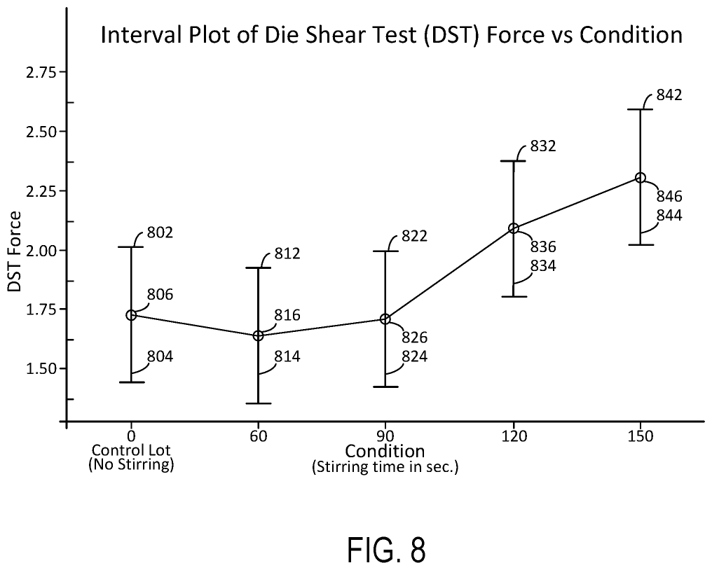

FIG. 8 illustrates a graph of experimental data related to die shear test (DST) force versus a condition of stirring times, in accordance with various examples of the present disclosure. In reference to FIG. 2C, FIG. 3A, FIG. 7A, and FIG. 8, stirring time conditions are related to step 718 of stirring die-bonding paste 240, possibly also with fillers 244, for a predetermined amount of time to produce homogenized die-bonding paste 256. According to various examples, different stirring times may result in different degrees of homogenization of die-bonding paste 240 (and fillers 244). As the testing data will indicate, a greater mixing time may produce more uniform homogenization which may result in a greater degree of adhesion of semiconductor chip 308 to substrate 276. Improvement of this adhesion property may be measured as by a greater die shear test (DST) force (e.g., lateral force) measured in kilograms (kg) required to separate a mounted component from a substrate, as measured according to MIL-STD-883 method 2019.9, for example.

FIG. 8 illustrates a control lot 802, corresponding to no stirring or zero seconds stirring, was found to require a die shear test force 804 ranging in an interval between about 1.47 kg to about 2.05 kg with a mean force of about 1.70 kg. In this example, a pooled standard deviation was used to calculate the intervals. A control lot 812, corresponding to 60 seconds of stirring time, was found to require a die shear test force 814 ranging between about 1.37 kg to about 1.93 kg with a mean force of about 1.63 kg. A control lot 822, corresponding to 90 seconds of stirring time, was found to require a die shear test force 824 ranging between about 1.43 kg to about 2.00 kg with a mean force of about 1.65 kg. A control lot 832, corresponding to 120 seconds of stirring time, was found to require a die shear test force 834 ranging between about 1.80 kg to about 2.37 kg with a mean force of about 2.09 kg. A control lot 842, corresponding to 150 seconds of stirring time, was found to require a die shear test force 844 ranging between about 2.05 kg to about 2.60 kg with a mean force of about 2.30 kg. In this manner, the test data indicates that a stirring time of at least 90 seconds up to 150 seconds may produce a stronger adhesion of semiconductor dies to substrates, as described herein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The various embodiments were chosen and described in order to best explain the principles of the invention and the practical application, and to enable others of ordinary skill in the art to understand the invention for various embodiments with various modifications as are suited to the particular use contemplated.

What is claimed is:

1. A method of manufacturing a semiconductor device, the method comprising:
(a) preparing a substrate;
(b) after (a), cleaning a chip mounting surface of the substrate;
(c) after (b), supplying a homogenized die-bonding paste onto the chip mounting surface of the substrate, and attaching a semiconductor chip on the chip mounting surface of the substrate via the homogenized die-bonding paste, the semiconductor chip having a front surface, a back surface opposite the front surface, and a first electrode formed on the front surface;
(d) after (c), curing the homogenized die-bonding paste;
(e) after (d), electrically connecting the first electrode of the semiconductor chip with a first terminal of the substrate via a first wire; and
(f) after (e), sealing the semiconductor chip and the first wire with a sealing resin,
wherein the homogenized die-bonding paste used in (c) is initially provided as an unstirred die-bonding paste including a plurality of Ag fillers, and
wherein, in (c), the homogenized die-bonding paste is supplied onto the chip mounting surface of the substrate after the unstirred die-bonding paste along with the plurality of Ag fillers is stirred for a first predetermined time period.

2. The method according to claim 1, wherein, in (b), the chip mounting surface of the substrate is cleaned by a plasma cleaning method using an Ar gas.

3. The method according to claim 1,
wherein the substrate has:
the first terminal; and
a second terminal disposed on the chip mounting surface,
wherein the semiconductor chip further has:
the front surface;
the back surface opposite the front surface;
the first electrode formed on the front surface; and
a second electrode formed on the back surface,
wherein, in (b), a surface of the first terminal and the chip mounting surface of the second terminal are cleaned,
wherein, in (c), the die-bonding paste is supplied onto the chip mounting surface of the second terminal, and
wherein, in (e), the second electrode of the semiconductor chip is electrically connected with the second terminal of the substrate via the homogenized die-bonding paste.

4. The method according to claim 1, wherein, in (c), the semiconductor chip is supplied onto the chip mounting surface of the substrate beginning within a second predetermined time period after the die-bonding paste is supplied onto the chip mounting surface of the substrate.

5. The method according to claim 4, wherein the second predetermined time period is less than sixty minutes.

6. The method according to claim 1, wherein, in (c), the homogenized die-bonding paste is stirred with a vibration for the first predetermined time period before the homogenized die-bonding paste is supplied onto the chip mounting surface of the substrate.

7. The method according to claim 6,
wherein, in (c), the homogenized die-bonding paste is stirred with a vibration at 40000 vibrations per minute for the first predetermined time period before the homogenized die-bonding paste is dispensed onto the chip mounting surface of the substrate, and
wherein the first predetermined time period is at least 90 seconds and not more than 150 seconds.

8. The method according to claim 7, wherein the unstirred die-bonding paste used in (c) is a silver-sintered epoxy paste including the plurality of Ag fillers.

9. The method according to claim 8, wherein the unstirred die-bonding paste used in (c) is the silver-sintered epoxy paste including the plurality of Ag fillers and a plurality of AlN fillers.

10. The method according to claim 1,
wherein, in (c), the homogenized die-bonding paste is supplied onto the chip mounting surface of the substrate by using a dispenser including:
a nozzle;
a syringe arranged above the nozzle and connected to the nozzle; and
a piston arranged in the syringe, and
wherein, in (c), the homogenized die-bonding paste is stirred in the syringe, and is dispensed onto the chip mounting surface of the substrate by pushing the homogenized die-bonding paste out with the piston.

11. The method according to claim 1,
wherein the substrate is a wiring substrate including a glass fiber and an epoxy resin, and
wherein, in (f), the semiconductor chip and the wire are sealed with the sealing resin by using a compression molding method.

12. The method according to claim 11, further comprising:
(g) after (f), heating a molded package including the semiconductor chip, which is obtained by performing (f), in a state that the molded package is clamped with a first metal plate and a second metal plate.

13. A method of manufacturing a semiconductor module, the method comprising:
(a) preparing a substrate having a chip mounting surface with a first bonding region and a second bonding region;
(b) after (a), cleaning each of the first bonding region and the second bonding region;
(c) after (b), supplying a homogenized die-bonding paste onto each of the first bonding region and the second bonding region;
(d) after (c), attaching a first semiconductor chip on the first bonding region via the homogenized die-bonding paste supplied onto the first bonding region, the first semiconductor chip having a first front surface, a first back surface opposite the first front surface, and a first electrode formed on the first front surface;
(e) after (d), attaching a second semiconductor chip on the second bonding region via the homogenized die-bonding paste supplied onto the second bonding region, the second semiconductor chip having a second front surface, a second back surface opposite the second front surface, and a second electrode formed on the second front surface;
(f) after (e), curing the homogenized die-bonding paste supplied to each of the first bonding region and the second bonding region;
(g) after (f), electrically connecting the first electrode of the first semiconductor chip with a first terminal of the substrate via a first wire, and electrically connecting the second electrode of the second semiconductor chip with a second terminal of the substrate via a second wire; and
(h) after (g), sealing the first semiconductor chip, the second semiconductor chip, the first wire and the second wire with a sealing resin by compression molding,
wherein the die-bonding paste used in (c) is initially provided as an unstirred die-bonding paste including a plurality of Ag fillers, and
wherein, in (c), the homogenized die-bonding paste is supplied onto each of the first bonding region and the second bonding region after the unstirred die-bonding paste along with the plurality of Ag fillers is stirred for a first predetermined time period.

14. The method according to claim 13, further comprising:
(i) after (h), heating a molded package including the first semiconductor chip and the second semiconductor chip, which is obtained by performing (h), in a state that the molded package is clamped between a first metal plate and a second metal plate.

15. The method according to claim 14, wherein, in (b), each of the first bonding region and the second bonding region is cleaned by a plasma cleaning method using an Ar (Argon) gas.

16. The method according to claim 13,
wherein the first semiconductor chip is comprised of one of GaN and GaAs,
wherein the second semiconductor chip is comprised of one of Si and SiC, and
wherein a flatness of the first back surface of the first semiconductor chip is lower than a flatness of the second back surface of the second semiconductor chip.

17. A semiconductor device comprising:
a substrate;
a semiconductor chip mounted on a chip mounting surface of the substrate via a homogenized die-bonding paste that is cured;
a wire electrically connected a first electrode of the semiconductor chip with a terminal; and
a sealing body sealing the semiconductor chip and the wire,
wherein the homogenized die-bonding paste includes a plurality of Ag fillers and a plurality of AlN fillers,
wherein a density of the plurality of AlN fillers per unit volume is less than a density of the plurality of Ag fillers per unit volume.

18. The semiconductor device according to claim 17, wherein a diameter of each of the plurality of AlN fillers is smaller than a diameter of each of the plurality of Ag fillers.

19. The semiconductor device according to claim 18,
wherein the semiconductor chip further has:
a front surface;
a back surface opposite the front surface;
the first electrode formed on the front surface; and
a second electrode formed on the back surface,
wherein the semiconductor chip is mounted on the chip mounting surface of the substrate such that the back surface of the semiconductor chip faces the chip mounting surface of the substrate, and
wherein the second electrode of the semiconductor chip is electrically connected with the substrate via the homogenized die-bonding paste.

20. The semiconductor device according to claim 18,
wherein the homogenized die-bonding paste was stirred at 40000 vibrations per minute for at least 90 seconds and not more than 150 seconds prior to mounting the semiconductor chip.
